(19) United States
(12) Patent Application Publication
(10) Pub. No.: US 2012/0126672 A1
(43) Pub. Date: May 24, 2012

(54) CASING OF ELECTRONIC DEVICE HAVING BASE PLATE AND SUPPORTING POST

(75) Inventors: JI-FENG QIU, Shenzhen City (CN); TING-TING ZHAO, Shenzhen City (CN); XIAO-HUI ZHOU, Shenzhen City (CN); HONG LI, Shenzhen City (CN)

(73) Assignees: HON HAI PRECISION INDUSTRY CO., LTD., Tu-Cheng (TW); HONG FU JIN PRECISION INDUSTRY(ShenZhen) CO., LTD., Shenzhen City (CN)

(21) Appl. No.: 12/974,102

(22) Filed: Dec. 21, 2010

(30) Foreign Application Priority Data
Nov. 22, 2010 (CN) 201010553225.1

(51) Int. Cl. H05K 5/02; A47B 96/00

(52) U.S. Cl. 312/223.1; 312/351.2

(57) ABSTRACT

A casing includes a base plate and a supporting post extending upwardly from the base plate. The base plate and the supporting post are integrally formed as a single monolithic piece from the same material. The supporting post axially defines a fixing hole therein. The fixing hole has an opening at a top free end of the supporting post. The fixing hole includes a first section adjacent to the opening, a second section far from the opening and spaced from the first section, and a chamfer section between the first section and the second section. The first section has a diameter larger than that of the second section.

### BACKGROUND

1. Technical Field

The disclosure generally relates to casings of electronic devices, and more particularly to a casing having a supporting post.

2. Description of Related Art

An electronic device, such as a portable DVD (digital video disc) player, a notebook computer or a projector, usually includes a casing for accommodating components of the electronic device, such as a circuit board, a motor or a driving mechanism. The casing is made of plastic, and includes a base plate and a plurality of supporting posts integrally formed with the base plate. Each supporting post axially defines a fixing hole therein. Screws used to attach the components to the supporting post are typically self-tapping screws, which create a thread in the supporting post during the first insertion of the screw therein.

Sometimes, the supporting posts need to be formed longer than normal, to meet particular structural requirements. However, the interior diameter of the fixing hole may need to be kept unchanged. When the casing is formed by an injection molding machine, melted plastic ejected from the nozzle of the injection molding machine may not flow sufficiently fast to a region of the injection mold where a top portion of the supporting post is formed. Such melted plastic may become solidified or semi-solidified before it reaches the region for forming the top portion of the supporting post. Thus a phenomenon called cold slag occurs, which creates stress concentration at the top portion of the formed supporting post. As a result, the molded casing may be unstable and unreliable. In particular, when a self-tapping screw is inserted into the fixing hole of the supporting post for tapping, the supporting post is easily cracked by the screw.

What is needed, therefore, is a casing to overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead placed upon clearly illustrating the principles of the present embodiments. Moreover, in the drawings, like reference numerals designate corresponding parts throughout the views.

FIG. 1 is an isometric view of part of a casing for an electronic device in accordance with an exemplary embodiment of the present disclosure.

FIG. 2 is an enlarged, cross-sectional view of part of the casing of FIG. 1, taken along line II-II thereof.

### DETAILED DESCRIPTION

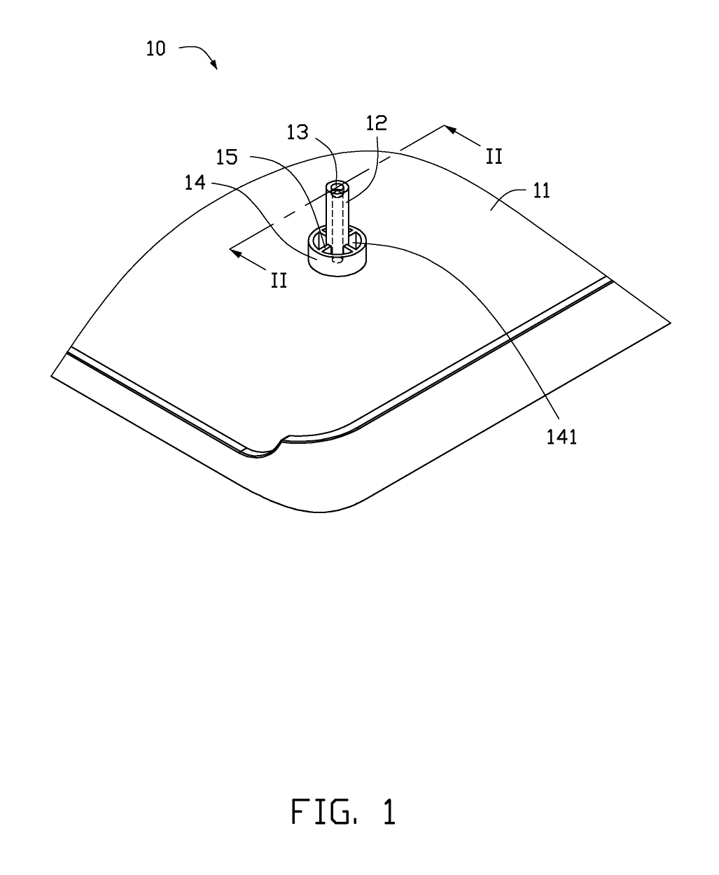

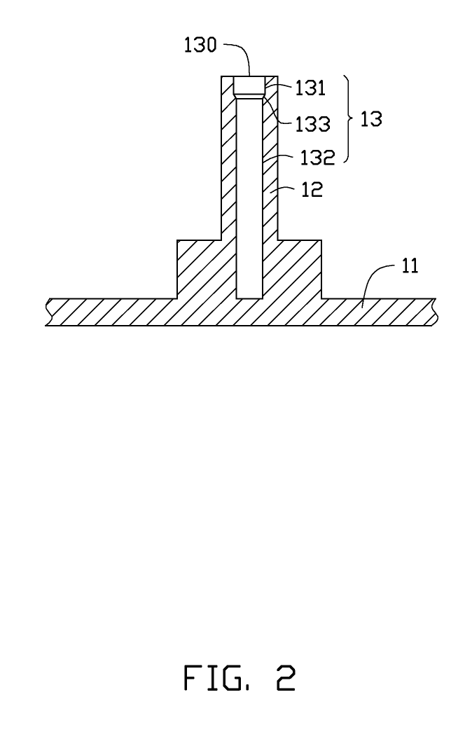

Referring to FIGS. 1-2, a casing 10 for an electronic device according to an exemplary embodiment of the present disclosure is shown. The casing 10 can be used in an electronic device, such as a portable DVD player, a notebook computer or a projector, for supporting and fixing components of the electronic device.

The casing 10 includes a base plate 11, and a supporting post 12 integrally extending upwardly from the base plate 11. The base plate 11 and the supporting post 12 of the casing 10 are integrally formed as a single monolithic piece from plastic via injection molding. In other words, the base plate 11 and the supporting post 12 are portions of a single body formed from the same material (i.e., plastic). The supporting post 12 axially defines a step-shaped fixing hole 13 therein. The fixing hole 13 has an opening 130 at a top free end of the supporting post 12, for a self-tapping screw to be inserted therein.

The fixing hole 13 includes a cylindrical first section 131 adjacent to the opening 130, a cylindrical second section 132 far from the opening 130 and spaced from the first section 131, and a frustoconical chamfer section 133 between the first section 131 and the second section 132. The first section 131 has an interior diameter larger than that of the second section 132. In the illustrated embodiment, the first section 131 has a circular cylindrical shape, the second section 132 has a circular cylindrical shape, and the chamfer section 133 has a circular frustoconical shape. The chamfer section 133 is located much nearer to the opening 130 than to a bottom of the fixing hole 13. That is, an axial length of the first section 131 is much greater than that of the second section 132.

The base plate 11 forms an annular plate 14 thereon, around the supporting post 12. An annular space 141 is defined between the annular plate 14 and the supporting post 12. The base plate 11 further forms a plurality of ribs 15 thereon. The ribs 15 are disposed in the annular space 141, and are evenly angularly spaced from each other around a circumference of the supporting post 12. Each rib 15 connects the supporting post 12 with the annular plate 14 to strengthen the supporting post 12.

In the casing 10, the fixing hole 13 of the supporting post 12 has a chamfer section 133 located near the top free end of the supporting post 12. The first section 131 above the chamfer section 133 has an interior diameter larger than that of the second section 132 below the chamfer section 133. When the casing 10 is formed by an injection molding machine, melted plastic from a nozzle of the injection molding machine can easily flow quickly to a region of the injection mold where a top portion of the supporting post 12 is formed. Thus the phenomenon of cold slag is reduced or even eliminated, thereby reducing or even eliminating stress concentration at the top portion of the supporting post 12. The quality of the molded casing 10 is improved, and the casing 10 can provide stable and reliable service.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A casing comprising:
a base plate; and
a supporting post extending upwardly from the base plate, the base plate and the supporting post being integrally formed as a single monolithic piece from the same material, the supporting post axially defining a fixing hole therein, the fixing hole having an opening at a top free end of the supporting post, the fixing hole comprising a first section adjacent to the opening, a second section far from the opening and spaced from the first section, and a chamfer section between the first section and the second section, the first section having a diameter larger than that of the second section.

2. The casing of claim 1, wherein the supporting post is formed from plastic.

3. The casing of claim 1, wherein the casing is an electronic device casing.

4. The casing of claim 3, wherein the casing is one of a portable digital video disc player casing, a notebook computer casing, and a projector casing.

5. The casing of claim 1, further comprising a plurality of ribs, wherein the base plate comprises an annular plate around the supporting post, an annular space is defined between the annular plate and the supporting post, and the ribs are disposed in the annular space, with each rib connecting the supporting post with the annular plate.

6. The casing of claim 5, wherein the ribs are evenly angularly spaced from each other.

7. The casing of claim 5, wherein the ribs, the base plate and the supporting post are integrally formed as a single monolithic piece from the same material.

8. The casing of claim 1, wherein an axial length of the first section is greater than that of the second section.

9. The casing of claim 1, wherein the first section has a circular cylindrical shape, the second section has a circular cylindrical shape, and the chamfer section has a circular frustoconical shape.

10. A one-piece base plate for supporting an electronic component, the base plate comprising:
a main body; and
a supporting post extending from the main body, the supporting post axially defining a fixing hole therein, the fixing hole comprising a first section exposed at a free end of the supporting post, a second section adjacent to the main body, and a tapered interconnecting section intercommunicating the first section and the second section, the first section having a diameter larger than that of the second section, and the interconnecting section located nearer to the free end of the supporting post than to an inmost end of the second section.

11. The one-piece base plate of claim 10, wherein the supporting post is formed from plastic.

12. The one-piece base plate of claim 10, further comprising an annular plate around the supporting post, an annular space is defined between the annular plate and the supporting post, and the ribs are disposed in the annular space, with each rib connecting the supporting post with the annular plate.

13. The one-piece base plate of claim 12, wherein the ribs are evenly angularly spaced from each other.

14. The one-piece base plate of claim 12, wherein the base plate and the supporting post are integrally formed as a single monolithic piece from the same material.

15. The one-piece base plate of claim 10, wherein an axial length of the first section is greater than that of the second section.

16. The one-piece base plate of claim 10, wherein the first section has a circular cylindrical shape, the second section has a circular cylindrical shape, and the interconnecting section has a circular frustoconical shape.
